(19) United States
(12) Patent Application Publication
(10) Pub. No.: US 2008/0105954 A1
(43) Pub. Date: May 8, 2008

(54) Group III nitride based semiconductor device having trench structure or mesa structure and production method therefor

(75) Inventors: Masahito KODAMA, Aichi-ken (JP); Eiko HAYASHI, Aichi-ken (JP); Masahiro SUGIMOTO, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignees: KABUSHIKI KAISHA TOYOTA CHUO KENKYUSHO, Aichi-ken (JP); TOYOTA JIDOSHA KABUSHIKI KAISHA, Aichi-ken (JP)

(21) Appl. No.: 11/976,451

(22) Filed: Oct. 24, 2007

(30) Foreign Application Priority Data
Oct. 24, 2006 (JP) 2006-289056

(51) Int. Cl. H01L 29/06; H01L 21/306

(52) U.S. Cl. 257/623; 438/745; 257/E21.215; 257/E29.006

(57) ABSTRACT

A group III nitride based semiconductor device which has a trench or mesa structure and of which leakage of current and reduction of breakdown voltage are prevented.

A GaN layer 2 was grown on a C-plane sapphire substrate 1, and a T-shaped USG film 3 was formed on the GaN layer 2 so that side surfaces of the USG film 3 were arranged parallel to A-plane and M-plane of the GaN layer 2. Thereafter, by using the USG film 3 as a mask, the GaN layer 2 was dry-etched. As is clear from FIGS. 2A and 2B, the M-plane is less roughened as compared with the A-plane. Subsequently, wet-etched was performed by use of an aqueous TMAH solution. As is clear from FIGS. 2C and 2D, roughness of the A-plane and the M-plane are removed, and, particularly, the M-plane assumes a mirror surface. Thus, through provision of M-plane side surfaces of a trench or an etching-formed mesa, leakage of current and reduction of breakdown voltage of a group III nitride based semiconductor device can be prevented.

### TECHNICAL FIELD

The present invention relates to a semiconductor device comprising a group III nitride semiconductor with a trench or mesa structure, wherein a side surface of a trench or a mesa formed by etching has a specific crystal orientation. The present invention also relates to a method for producing the semiconductor device.

### BACKGROUND ART

Group III nitride based semiconductors have been widely employed in light-emitting devices (e.g., an LED). Since group III nitride based semiconductors potentially exhibit high breakdown voltage, extensive studies have been conducted for the development of such semiconductors as materials for, for example, high-frequency power devices. For producing a device having high breakdown voltage, the structure of the device is desirably vertical structure and for reducing on-resistance, a trench-type structure is desirably employed.

Semiconductor devices comprising such a trench-type group III nitride based semiconductor have been disclosed; for example, the structure of a U-MOS is disclosed in Patent Document 1, and a trench-type HEMT is disclosed in Patent Document 2.

Patent Document 1: Japanese kohyo Patent Publication No. 2003-517725

Patent Document 2: Japanese Patent Application Laid-Open (kokai) No. 2004-260140

### DISCLOSURE OF THE INVENTION

### Problems to be Solved by the Invention

However, when a trench or mesa structure is formed in a group III nitride based semiconductor through dry etching, an etched cross section is considerably roughened. Such roughness causes leakage of current or reduction of breakdown voltage, resulting in deterioration in performance of produced semiconductor devices.

Patent Documents 1 and 2 neither describe nor discuss crystal orientation of a side surface of a trench or mesa formed by etching.

In view of the foregoing, an object of the present invention is to realize a group III nitride based semiconductor device, in which a trench or mesa structure is formed so as to suppress generation of roughness on side surfaces of a trench or mesa formed by etching, whereby leakage of current and reduction of breakdown voltage are prevented. Another object of the present invention is to provide a method for producing the group III nitride based semiconductor device.

### Means for Solving the Problems

In a first aspect of the present invention, there is provided a semiconductor device which comprises a group III nitride based semiconductor containing Ga as an essential component and which has a trench or mesa structure, characterized in that, among etched side surfaces of a trench or mesa formed by etching, at least a surface, i.e., active region for operating the semiconductor device is M-plane.

As used herein, “group III nitride based semiconductor containing Ga as an essential component” refers to any of group III nitride based semiconductors represented by the formula AlₓGa_{y}In_{z}N (x+y+z=1, 0≦x, y, z≦1), except for AlN and InN. Such a group III nitride based semiconductor may be doped with an impurity to be of an n-type or a p-type.

As used herein, “surface for operating the semiconductor device (hereinafter may be referred to as an ‘operating surface’)” refers to a main regional surface employed for operating the semiconductor device. For example, when the semiconductor device is an LED, the operating surface is an SQW or MQW surface, and when the semiconductor device is an FET, the operating surface is a channel surface. Meanwhile, when the semiconductor device is a laser diode, the operating surface may be an SQW or MQW surface or a resonator end surface.

The present inventors have conducted studies on roughness of etched side surfaces of a trench or mesa after dry etching, and have found that the roughness varies depending on the crystal orientation, and, particularly, M-plane is less roughened as compared with other crystal planes. According to the first aspect of the present invention, which is based on this finding, since at least an operating surface among side etched surfaces of a trench or mesa is M-plane, leakage of current and reduction of breakdown voltage are prevented in the semiconductor device. According to a second aspect of the present invention, each of the etched side surfaces of the trench or mesa formed by etching is M-plane. In this case, leakage of current and reduction of breakdown voltage are prevented more effectively, which is preferred.

A third aspect of the present invention is drawn to a specific embodiment of the semiconductor device according to the first or second aspect of the invention, wherein roughness of the dry-etched side surface of the trench or mesa is removed through wet etching.

A solution employed for the wet etching may be a solution of an alkali such as KOH or NaOH. Especially according to a fourth aspect of the present invention, an aqueous TMAH solution (tetra methyl ammonium hydroxide: (CH₃)₄NOH) solution) is preferably employed. This is because aqueous TMAH solution can be employed at 50 to 100° C. and at a concentration of 5 to 50%, and is easy to handle. In addition, aqueous TMAH solution is easy to wash out. Aqueous TMAH solution can be employed for etching of any crystal plane (other than C-plane) of a group III nitride based semiconductor. When M-plane is wet-etched, roughness is removed, and the thus-etched plane assumes a mirror surface. When A-plane is subjected to etching, roughness is removed, but numerous fine streaks are observed. The streaks assume M-plane.

A fifth aspect of the present invention is drawn to a specific embodiment of the semiconductor device according to the second to fourth aspects of the invention, wherein the semiconductor device has a honeycomb structure comprising the trench or mesa structure. When each of the etched side surfaces of the trench or mesa formed by etching is M-plane, a hexagonal-prismatic trench or column whose side surfaces are M-plane is formed. In the fifth aspect of the invention, such a hexagonal-prismatic trench or column is employed for forming a honeycomb structure. Generally, a honeycomb structure has a cross-section of hexagons having the same size, and such hexagons can be arrayed at high density in the cross-section. In addition, a honeycomb structure is very robust. Therefore, when a semiconductor has a honeycomb structure comprising a trench or mesa structure, a semiconductor device can be efficiently produced on a substrate.

A sixth aspect of the present invention is drawn to a specific embodiment of the semiconductor device according to the first to fourth aspects of the invention, wherein the semiconductor device has a super-junction structure comprising the trench or mesa structure. Employment of a super-junction structure can reduce on-resistance of the semiconductor device.

A seventh aspect of the present invention is drawn to a specific embodiment of the semiconductor device according to the first to sixth aspects of the invention, wherein the semiconductor device is an HEMT, a U-MOS, an LED, or a laser diode.

An eighth aspect of the present invention is drawn to a specific embodiment of the semiconductor device according to the sixth aspect of the invention, wherein the semiconductor device is a pn diode or a Schottky diode.

A ninth aspect of the present invention is drawn to a specific embodiment of the semiconductor device according to the first to fourth aspects of the invention, wherein the semiconductor device has a Bragg reflector, a mirror surface for use in a resonator of a laser diode, or a waveguide, each comprising the trench or mesa structure. Such a Bragg reflector can comprise, for example, an AlGaN/GaN multi-layer structure.

In a tenth aspect of the present invention, there is provided a semiconductor device which comprises a group III nitride based semiconductor containing Ga as an essential component and which has a trench or mesa structure, characterized in that, among etched side surfaces of a trench or mesa, at least an operating surface is A-plane; and roughness of the dry-etched side surfaces of the trench or mesa is removed by an aqueous TMAH solution.

In an eleventh aspect of the present invention, there is provided a method for producing a semiconductor device which comprises a group III nitride based semiconductor containing Ga as an essential component and which has a trench or mesa structure, characterized in that the method comprises a step of forming a trench or mesa structure so that, among etched side surfaces of the trench or mesa, at least a surface for operating the semiconductor device is M-plane.

A twelfth aspect of the present invention is drawn to a specific embodiment of the production method according to the eleventh aspect of the invention, wherein each of the etched side surfaces of the trench or mesa is M-plane.

A thirteenth aspect of the present invention is drawn to a specific embodiment of the production method according to the eleventh or twelfth aspect of the invention, wherein the method further comprises, after the step of forming a trench or mesa structure, a step of wet etching the side surface of the trench or mesa to eliminate damage.

A fourteenth aspect of the present invention is drawn to a specific embodiment of the production method according to the eleventh to thirteenth aspects of the invention, wherein a solution employed in wet etching is an aqueous TMAH solution.

Such a trench or mesa structure is formed through dry etching (e.g., reactive ion etching).

### EFFECTS OF THE INVENTION

According to the first aspect of the present invention, since, in a semiconductor device comprising a group III nitride based semiconductor containing Ga as an essential component, at least an operating surface among etched side surfaces of a trench or mesa is M-plane, leakage of current and reduction of breakdown voltage can be prevented in the semiconductor device. As described in relation to the third or fourth aspect of the present invention, when roughness of the etched side surface of the trench or mesa is removed through wet etching, leakage of current and reduction of breakdown voltage are prevented more effectively. Therefore, employment of such a trench or mesa structure realizes various structures in which leakage of current and reduction of breakdown voltage are prevented, whereby a variety of vertical semiconductor devices or trench-type semiconductor devices can be realized. Examples of such devices include semiconductor devices having, for example, a honeycomb structure or a super-junction structure; HEMTs, U-MOSs, LEDs, and laser diodes (the seventh aspect); and semiconductor devices including a Bragg reflector or a waveguide (the ninth aspect). Since M-plane which has been wet etched with an aqueous TMAH solution assumes a mirror surface, and is less roughened as compared with a cleavage surface, the M-plane can be employed as a mirror surface for a resonator of a laser diode.

According to the eleventh to fourteenth aspects of the present invention, there can be produced a semiconductor device in which leakage of current and reduction of breakdown voltage are prevented.

### BRIEF DESCRIPTION OF THE DRAWINGS

FIG. 1 is a top view of a USG film 3 of Embodiment 1.

FIG. 2A to 2D are SEM photographs of a sample produced in Embodiment 1.

FIG. 3 is SEM photograph of a mesa structure formed in Embodiment 2.

FIGS. 4A and 4B are cross-sections of a U-MOS of Embodiment 3.

FIGS. 5A and 5B are cross-sections of an HEMT of Embodiment 4.

FIG. 6 is a cross-section of an LED of Embodiment 5.

FIG. 7 is a cross-section of a super-junction pn diode according to Embodiment 6.

### BEST MODES FOR CARRYING OUT THE INVENTION

Specific embodiments of the present invention will next be described with reference to the drawings, but the present invention is not limited to the embodiments.

### Embodiment 1

In Embodiment 1, a sample was produced as described below to investigate the crystal orientation dependence of roughness of side surfaces of a trench or mesa of a dry-etched group III nitride based semiconductor.

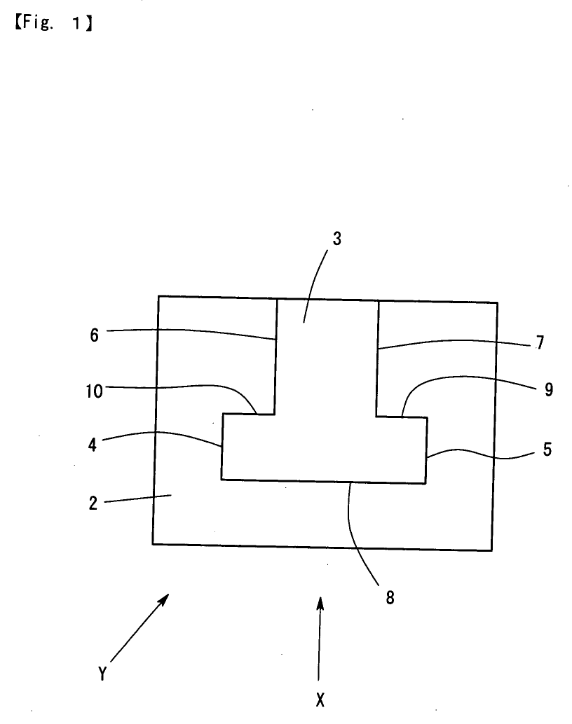

Firstly, a GaN layer 2 (thickness: 3 μm) was grown on a C-plane sapphire substrate 1, and a T-shaped USG film 3 was formed on the GaN layer 2 through photolithography and dry etching (FIG. 1). The USG film 3 was formed so that side surfaces 4 to 7 were arranged parallel to M-plane of the GaN layer 2, and side surfaces 8 to 10 were arranged parallel to A-plane of the GaN layer 2. Thereafter, by using the USG film 3 as a mask, the GaN layer 2 was dry-etched to a depth of 3 μm by use of a gas mixture of Cl₂ and BCl₃. Subsequently, the thus-produced sample was wet-etched by use of 25% aqueous TMAH solution at 85° C. for five minutes.

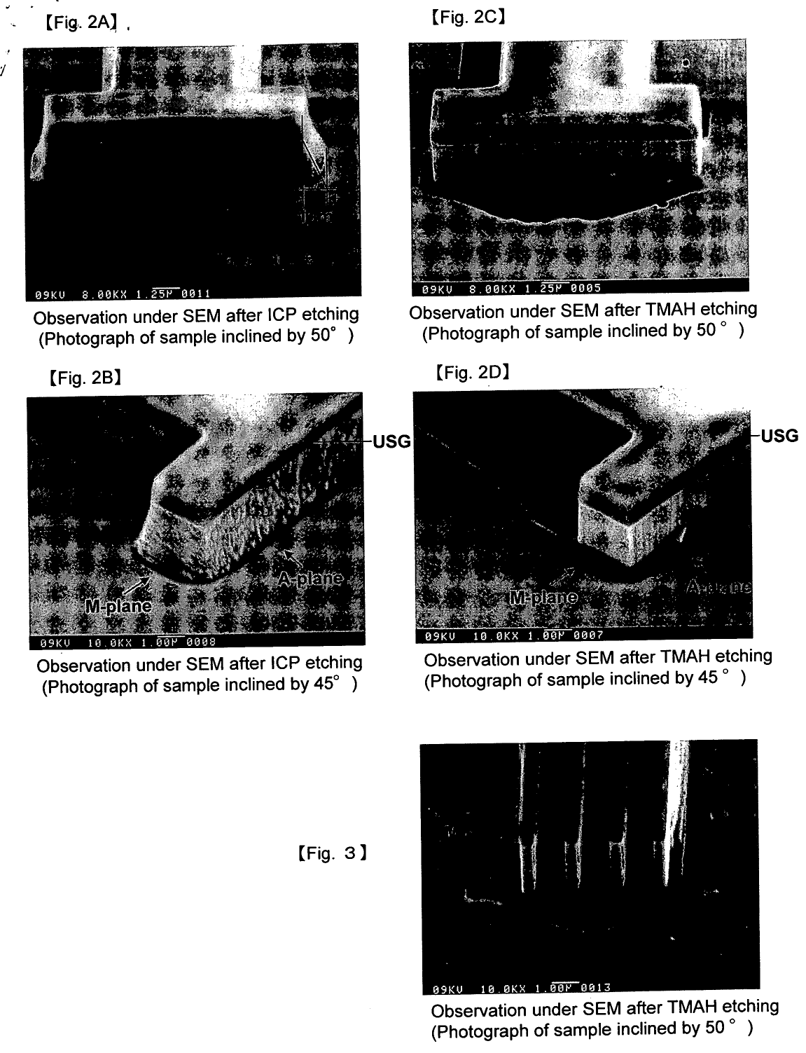

FIG. 2A is an SEM photograph of the dry-etched sample inclined by 50°, as taken in the direction shown by arrow X of FIG. 1; and FIG. 2B is an SEM photograph of the dry-etched sample inclined by 45°, as taken in the direction shown by arrow Y of FIG. 1. As is clear from FIG. 2A, the sample is etched so as to form a trapezoidal cross section (taper angle: about 71°). As is clear from FIG. 2B, M-plane of the GaN layer 2 is less roughened as compared with A-plane thereof. FIG. 2C is an SEM photograph of the sample after wet etching with the aqueous TMAH solution, as taken in the same direction as in the case of FIG. 2A; and FIG. 2D is an SEM photograph of the sample after wet etching with the aqueous TMAH solution, as taken in the same direction as in the case of FIG. 2B. As is clear from FIG. 2C, the trapezoidal cross section is changed into a rectangular cross section. As is clear from FIG. 2D, the M-plane has no roughness, and assumes a mirror surface; i.e., the M-plane assumes a very favorable surface. Similar to the M-plane, the A-plane has no roughness. However, the A-plane has fine streaks in a vertical direction, which streaks are constructed by M-plane.

As described above, a semiconductor device having a trench or mesa structure in which an operating surface is M-plane exhibits reduced leakage current and suppressed reduction of breakdown voltage, since the operating surface is less roughened. Particularly, wet etching with an aqueous TMAH solution is more effective, since M-plane does not exhibit roughness at all.

### Embodiment 2

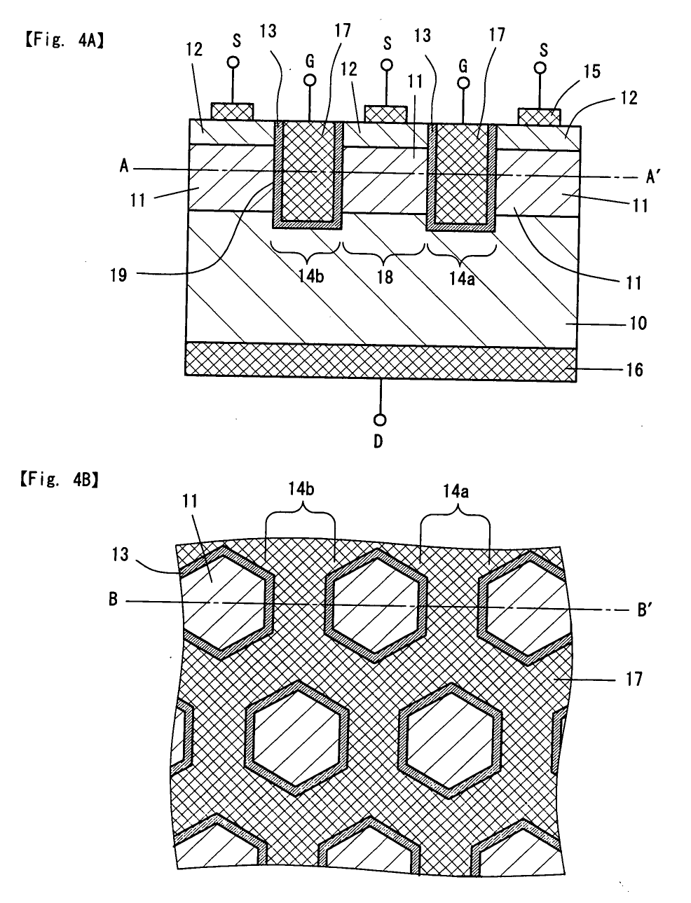

Similar to Embodiment 1, a GaN layer 2 (thickness: 3 μm) was formed on a C-plane sapphire substrate 1. Thereafter, the resultant product was dry-etched, to thereby form a mesa structure having parallel sheets (width: 0.3 μm, height: 3 μm each) in which wide surfaces of M-plane are aligned in parallel to one another, followed by wet etching with an aqueous TMAH solution. FIG. 3 is an SEM photograph of the mesa structure. Employment of such a mesa structure can produce a semiconductor device having a Bragg reflector or a super-junction structure, the device exhibiting reduced leakage current and suppressed reduction of breakdown voltage.

### Embodiment 3

FIG. 4 shows the structure of a U-MOS of Embodiment 3. FIG. 4A is a vertical cross-sectional view of the U-MOS shown in FIG. 4B, as taken along line B-B′; and FIG. 4B is a horizontal cross-sectional view of the U-MOS shown in FIG. 4A, as taken along line A-A′.

As shown in FIG. 4A, in the U-MOS of Embodiment 3, a p-GaN layer 11 is formed on an n-GaN layer 10; an n⁺-GaN layer 12 is formed on the p-GaN layer 11; source electrodes 15 are formed on the n⁺-GaN layer 12; and a drain electrode 16 is formed on the bottom surface of the n-GaN layer 10. Trenches 14a and 14b are formed so as to penetrate through the n⁺-GaN layer 12 and the p-GaN layer 11 and to reach the n-GaN layer 10. An SiO₂ insulating film 13 is formed so as to cover the side surfaces and bottom surface of each of the trenches 14a and 14b. A gate electrode 17 is formed so as to bury each trench covered with the insulating film 13. Each of the trenches 14a and 14b is formed so that each of the side surfaces thereof is M-plane, and so that, as shown in FIG. 4B, a region 18 including a portion of the n-GaN layer 10, the p-GaN layer 11, and the n⁺-GaN layer 12 forms a hexagonal-prismatic column whose side surfaces are M-plane. That is, the U-MOS has a honeycomb cell structure. During formation of the trenches 14a and 14b, wet etching is performed with an aqueous TMAH solution so as to prevent roughening of the side surfaces of the trenches 14a and 14b.

In the U-MOS of Embodiment 3, an interface 19 between the p-GaN layer 11 and the insulating film 13 serves as a channel. Since the side surfaces of the trenches 14a and 14b are prevented from being roughened, flow of leakage current and reduction of breakdown voltage are prevented.

### Embodiment 4

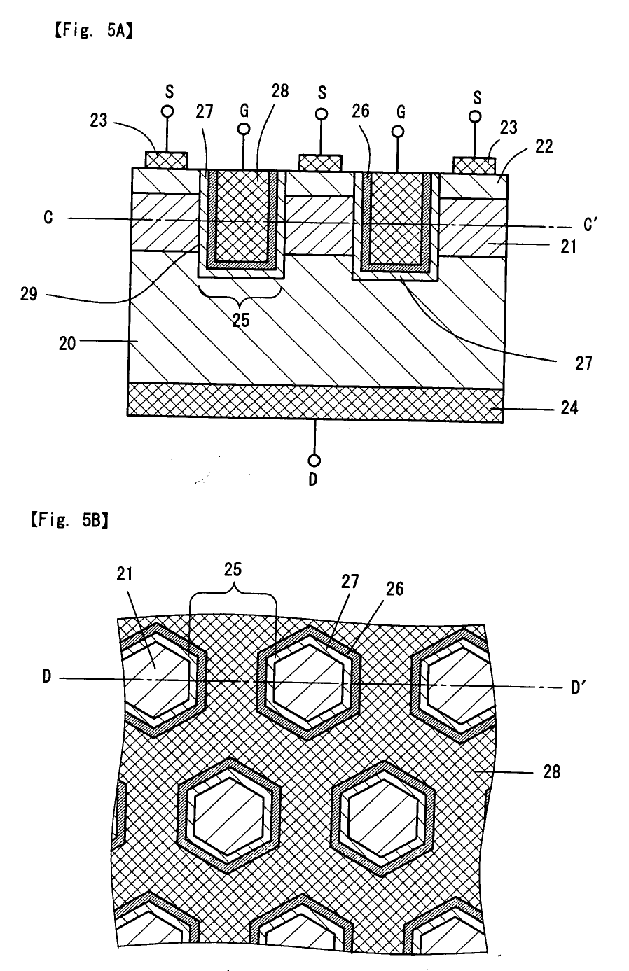

FIG. 5 shows the structure of an HEMT of Embodiment 4. FIG. 5A is a vertical cross-sectional view of the HEMT shown in FIG. 5B, as taken along line D-D′; and FIG. 5B is a horizontal cross-sectional view of the HEMT shown in FIG. 5A, as taken along line C-C′.

As shown in FIG. 5A, in the HEMT of Embodiment 4, an i-GaN layer 21 is formed on an n-GaN layer 20; an n⁺-GaN layer 22 is formed on the i-GaN layer 21; source electrodes 23 are formed on the n⁺-GaN layer 22; and a drain electrode 24 is formed on the bottom surface of the n-GaN layer 20. Trenches 25 are formed so as to penetrate through the i-GaN layer 21 and the n⁺-GaN layer 22 and to reach the surface of the n-GaN layer 20. An n-AlGaN layer 27 is formed so as to cover the side surfaces and bottom surface of each of the trenches 25, and an SiO₂ insulating film 26 is formed on the n-AlGaN layer 27. A gate electrode 28 is formed so as to bury each trench. Similar to Embodiment 3, each of the trenches 25 is formed so that each of the side surfaces thereof is M-plane, and so that, as shown in FIG. 5B, a region other than the trenches 25 forms a hexagonal-prismatic column whose side surfaces are M-plane. That is, the HEMT has a honeycomb cell structure. During formation of the trenches 25, wet etching is performed with an aqueous TMAH solution so as to prevent roughening of the side surfaces of the trenches 25.

In the HEMT of Embodiment 4, a junction surface 29 between the i-GaN layer 21 and the n-AlGaN layer 27 serves as a channel. Similar to Embodiment 3, flow of leakage current and reduction of breakdown voltage are prevented. In addition, since the HEMT has a trench structure, a wide channel can be provided, whereby on-resistance can be reduced.

### Embodiment 5

FIG. 6 is a cross-sectional view of the structure of an LED of Embodiment 5. An n⁺-GaN layer 31 is formed on a sapphire substrate 30, and a trench 32 is formed so as to penetrate through the n⁺-GaN layer 31 and to reach the surface of the sapphire substrate 30. An InGaN/GaN MQW layer 33 is formed so as to cover the side surfaces of the trench 32, and a p-GaN layer 34 is formed on the MQW layer 33. An electrode 35 is formed so as to bury the trench 32. An electrode 36 is formed on the top surface of the n⁺-GaN layer 31. An insulating film 37 is formed on the top surfaces of the n⁺-GaN layer 31, the MQW layer 33, and the p-GaN layer 34. The trench 32 of the n⁺-GaN layer 31 is formed so that each of the side surfaces thereof, which are in contact with the MQW layer 33, is M-plane. During formation of the trench 32, wet etching is performed with an aqueous TMAH solution so as to prevent roughening of the side surfaces of the trench 32. This LED is advantageous in that flow of leakage current and reduction of breakdown voltage can be prevented, as well as a wide light-emitting surface is provided by virtue of the trench structure of the LED.

### Embodiment 6

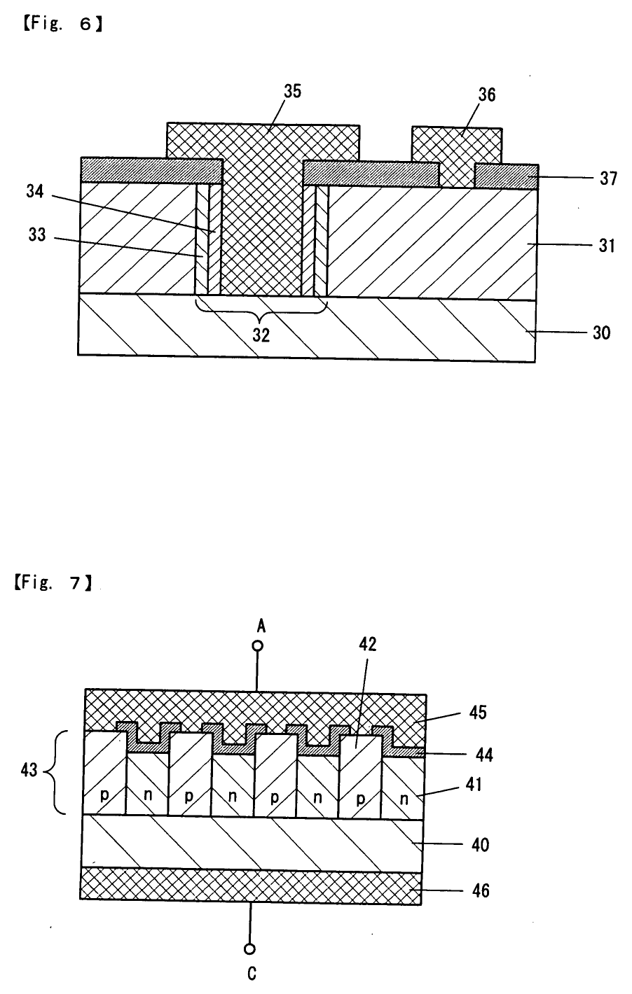

FIG. 7 is a cross-sectional view of the structure of a super-junction pn diode of Embodiment 6. The pn diode has, on an n⁺-GaN layer 40, a super-junction structure 43 including n-GaN layers 41 and p-GaN layers 42 which are alternately provided. An SiO₂ insulating film 44 is formed so as to cover each of the n-GaN layers 41 and portions of p-GaN layers 42 adjacent thereto. An electrode 45 is formed on the insulating films 44 and the p-GaN layers 42, and an electrode 46 is formed on the bottom surface of the n⁺-GaN layer 40.

In a manner similar to the case of the mesa structure shown in FIG. 3, the super-junction structure 43 was formed through the below-described procedure. An n-GaN layer 41 was formed on an n⁺-GaN layer 40, and the n-GaN layer 41 was dry-etched to form parallel sheets as shown in FIG. 3 so that surfaces of M-plane were in parallel with one another. Wet etching was performed with an aqueous TMAH solution so as to prevent roughening of M-plane. Thereafter, p-GaN layers 42 were formed so as to bury spaces provided between the n-GaN layers 41, whereby the super-junction structure was formed.

By virtue of the super-junction structure, the pn diode of Embodiment 6 exhibits high breakdown voltage. In addition, flow of leakage current and reduction of breakdown voltage can be prevented, by virtue of the effects of the present invention.

The semiconductor devices of Embodiments 3 to 6 are only examples of the semiconductor device of the invention having a trench or mesa structure, and the present invention can be applied to various other trench and mesa structures. For example, the present invention can be applied to structures of a Bragg reflector, a waveguide, etc.

### INDUSTRIAL APPLICABILITY

The present invention can realize various group III nitride based semiconductor devices having a trench or mesa structure, including a U-MOS and a trench-type HEMT.

1. A semiconductor device which comprises a group III nitride based semiconductor containing Ga as an essential component and which has a trench or mesa structure, characterized in that, among etched side surfaces of a trench or mesa, at least a surface for operating the semiconductor device is M-plane.

2. A semiconductor device according to claim 1, wherein each of the etched side surfaces of the trench or mesa is M-plane.

3. A semiconductor device according to claim 1, wherein roughness of the side surfaces of the trench or mesa is removed through wet etching.

4. A semiconductor device according to claim 2, wherein roughness of the side surfaces of the trench or mesa is removed through wet etching.

5. A semiconductor device according to claim 3, wherein wet etching is performed by use of an aqueous TMAH solution.

6. A semiconductor device according to claim 4, wherein wet etching is performed by use of an aqueous TMAH solution.

7. A semiconductor device according to claim 2, which has a honeycomb structure comprising the trench or mesa structure.

8. A semiconductor device according to claim 3, which has a honeycomb structure comprising the trench or mesa structure.

9. A semiconductor device according to claim 4, which has a honeycomb structure comprising the trench or mesa structure.

10. A semiconductor device according to claim 1, which has a super-junction structure comprising the trench or mesa structure.

11. A semiconductor device according to claim 2, which has a super-junction structure comprising the trench or mesa structure.

12. A semiconductor device according to claim 1, which is an HEMT, a U-MOS, an LED, or a laser diode.

13. A semiconductor device according to claim 2, which is an HEMT, a U-MOS, an LED, or a laser diode.

14. A semiconductor device according to claim 1, which is a pn diode or a Schottky diode.

15. A semiconductor device according to claim 2, which is a pn diode or a Schottky diode.

16. A semiconductor device according to claim 1, which has a Bragg reflector, a mirror surface for use in a resonator of a laser diode, or a waveguide, each being formed of the trench or mesa structure.

17. A semiconductor device according to claim 2, which has a Bragg reflector, a mirror surface for use in a resonator of a laser diode, or a waveguide, each being formed of the trench or mesa structure.

18. A semiconductor device which comprises a group III nitride based semiconductor containing Ga as an essential component and which has a trench or mesa structure, characterized in that, among etched side surfaces of a trench or mesa, at least a surface for operating the semiconductor device is A-plane; and roughness of the etched side surfaces of the trench or mesa is removed by an aqueous TMAH solution.

19. A method for producing a semiconductor device which comprises a group III nitride based semiconductor containing Ga as an essential component and which has a trench or mesa structure, characterized in that the method comprises a step of forming a trench or mesa structure so that, among etched side surfaces of the trench or mesa, at least a surface for operating the semiconductor device is M-plane.

20. A method for producing a semiconductor device according to claim 19, wherein each of the etched side surfaces of the trench or mesa is M-plane.

21. A method for producing a semiconductor device according to claim 19, which further comprises, after the step of forming a trench or mesa structure, a step of wet etching the etched side surfaces of the trench or mesa to eliminate damage.

22. A method for producing a semiconductor device according to claim 20, which further comprises, after the step of forming a trench or mesa structure, a step of wet etching the etched side surfaces of the trench or mesa to eliminate damage.

23. A method for producing a semiconductor device according to claim 21, wherein wet etching is performed by use of an aqueous TMAH solution.

24. A method for producing a semiconductor device according to claim 22, wherein wet etching is performed by use of an aqueous TMAH solution.
